(19) United States
(12) Patent Application Publication
(10) Pub. No.: US 2025/0246735 A1
(43) Pub. Date: Jul. 31, 2025

(54) VEHICLE SUBSTRUCTURE

(71) Applicant: TOYOTA JIDOSHA KABUSHIKI KAISHA, Toyota-shi Aichi-ken (JP)

(72) Inventors: Akiko MIZOBATA, Toyota-shi Aichi-ken (JP); Makoto KITADE, Miyoshi-shi Aichi-ken (JP)

(73) Assignee: TOYOTA JIDOSHA KABUSHIKI KAISHA, Toyota-shi Aichi-ken (JP)

(21) Appl. No.: 19/032,547

(22) Filed: Jan. 21, 2025

(30) Foreign Application Priority Data
Jan. 25, 2024 (JP) 2024-009747

(51) Int. Cl. H01M 50/242; B60R 16/033; H01M 10/613; H01M 10/625; H01M 10/6568; H01M 50/204; H01M 50/249; H01M 50/271

(52) U.S. Cl. CPC H01M 50/242; B60R 16/033; H01M 10/613; H01M 10/625; H01M 10/6568; H01M 50/204; H01M 50/249; H01M 50/271; H01M 2220/20

(57) ABSTRACT

A vehicle substructure includes: a battery cell; a housing case having an opening and accommodating the battery cell; a cover attached to the housing case in a state of covering the opening; a junction box, provided on top of the cover, for controlling the battery cell; a supply pipe for supplying a refrigerant for cooling the junction box and the battery cell; a first member covering the supply pipe, a second member for blocking an opposing surface where the supply pipe and the junction box face each other; and a third member for blocking an opposing surface where the supply pipe and the battery cell face each other.

### CROSS-REFERENCE TO RELATED APPLICATION(S)

The present application claims priority to and incorporates by reference the entire contents of Japanese Patent Application No. 2024-009747 filed in Japan on Jan. 25, 2024.

### BACKGROUND

The present disclosure relates to a vehicle substructure.

Japanese Laid-open Patent Publication No. 2022-153107 discloses that a battery control unit is disposed on the upper side of the first cover mounted in a state of covering the opening of the housing case having an opening disposed below the rear seat of the vehicle, the battery module in a sealed space formed by the first cover and the housing case technology is disclosed. In this technique, between the fastening flange portion of the outer peripheral portion and the housing case of the first cover, arranged a sealing member such as a rubber seal or a weather strip, and the first cover through the sealing member and the housing case in close contact.

Incidentally, in recent years, in the vehicle, by integrating the power converter and the battery cell, such as a battery control unit, has been achieved miniaturization and merchantability improvement. For this reason, in the vehicle, a water channel is provided to cool the power converter.

### SUMMARY

There is a need for providing a vehicle substructure capable of preventing the battery cells from being submerged by cooling water leaking from the water channel in the event of external impact.

According to an embodiment, a vehicle substructure includes: a battery cell; a housing case having an opening and accommodating the battery cell; a cover attached to the housing case in a state of covering the opening; a junction box, provided on top of the cover, for controlling the battery cell; a supply pipe for supplying a refrigerant for cooling the junction box and the battery cell; a first member covering the supply pipe, a second member for blocking an opposing surface where the supply pipe and the junction box face each other; and a third member for blocking an opposing surface where the supply pipe and the battery cell face each other.

### BRIEF DESCRIPTION OF THE DRAWINGS

FIG. 1 is a schematic diagram of a schematic configuration of a vehicle substructure according to an embodiment;

FIG. 2 is a perspective view illustrating a schematic configuration of a ring-shaped water stop member provided in the vehicle substructure according to an embodiment; and

FIG. 3 is a diagram schematically illustrating the action of the seal structure in the vehicle substructure according to an embodiment.

### DETAILED DESCRIPTION

In Japanese Laid-open Patent Publication No. 2022-153107 described above, since the sealing portion in which the sealing member is disposed is single, in the case where an impact is applied from the outside, when the water channel is damaged, there is a possibility that the battery cell is flooded by the cooling water leaked from the water channel.

Hereinafter, the vehicle substructure of the vehicle according to the embodiment of the present disclosure will be described with reference to the drawings. Note that the components in the following embodiments include those which can be substituted and easily by those skilled in the art, or those which are substantially the same. Further, the drawings referred to in the following description are only schematically showing the shape, size, and positional relationship to the extent that the contents of the present disclosure can be understood. In other words, the present disclosure is not limited only to the shape, size, and positional relationship exemplified in each of the figures.

Schematic configuration of the vehicle substructure

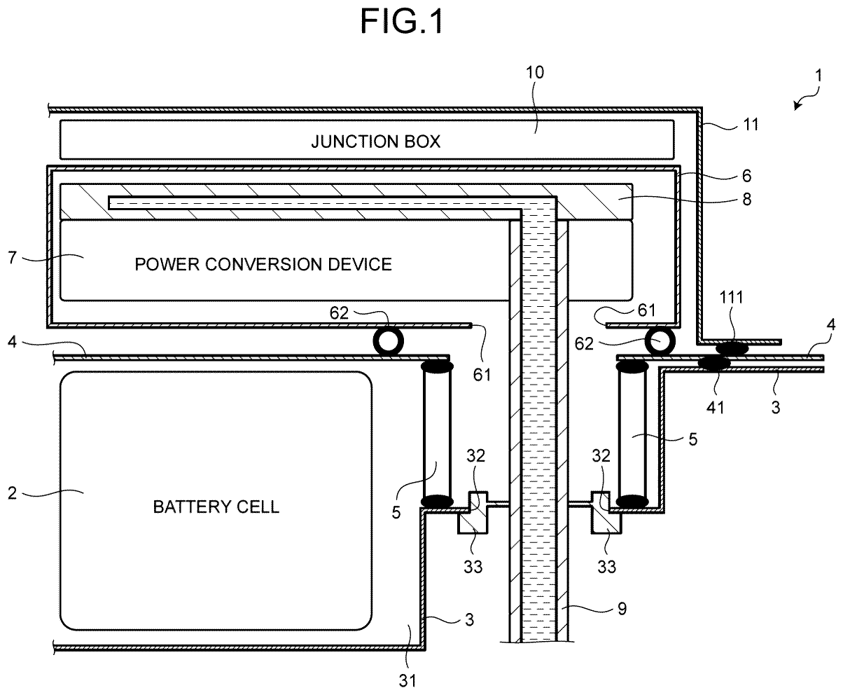

FIG. 1 is a diagram of a schematic configuration of a vehicle substructure according to an embodiment. A vehicle lower structure 1 of the vehicle illustrated in FIG. 1 includes, at least, a battery cell 2, a battery lower cover 3, a battery upper cover 4, a ring-shaped waterproof member 5, a waterproof case 6, a power conversion device 7, a water channel cover 8, a supply pipe 9, a junction box 10, and an equipment cover 11.

The battery cell 2 is constituted by using, for example, a lithium ion secondary battery or a nickel hydrogen secondary battery or the like.

The battery lower cover 3 has a box-shaped having an opening, to accommodate the battery cells 2 in the housing portion 31. The battery lower cover 3 has a box-like, a first hole 32 in which the supply tube 9 is inserted in the center. Furthermore, between the first hole 32 and the supply pipe 9, the water stop member 33 for preventing the water from entering or from the inside of the water from the outside leaks to the outside is provided. In one embodiment, the battery lower cover 3 functions as a housing case.

The battery upper cover 4 is attached in a state of covering the opening of the battery lower cover 3 through the water stop member 41. The waterproof case 6 is disposed on the upper surface of the battery upper cover 4. The water stop member 41 is constituted by using, for example, a rubber seal or a weather strip.

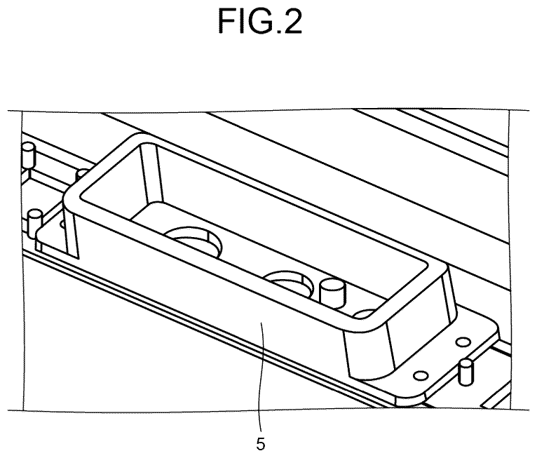

A ring-shaped water stop member 5 blocks the opposing surfaces where the supply pipe 9 and the battery cell 2 face each other. Specifically, the ring-shaped water stop member 5 blocks the opposing surface, between the battery lower cover 3 and the battery upper cover 4, where the supply tube 9 and the battery cell 2 faces. FIG. 2 is a perspective view illustrating a schematic configuration of a ring-shaped water stop member 5. As illustrated in FIG. 2, the ring-shaped water stop member 5 forms a ring-shaped having a thickness. The ring-shaped water cut-off member 5 may be a rubber seal such as a resin or an ethylene-propylene rubber (EPDM) or a weather strip. In one embodiment, the ring-shaped water stop member 5 functions as a third member.

The waterproof case 6 is a box-shaped, has a second hole 61 in which the supply pipe 9 is inserted, and houses the power conversion device 7 and the water channel cover 8 therein. The waterproof case 6 is disposed on the upper surface of the battery upper cover 4 through the ring-shaped water stop member 62. Furthermore, the waterproof case 6 blocks the opposing surfaces where the water passage cover 8, including a supply pipe 9, and the junction box 10. That is, the interior of the waterproof case 6 serves as a sealed space formed by the battery lower cover 3, the battery upper cover 4, a ring-shaped water stop member 5, the water stop member 41 and the ring-shaped water stop member 5. Thus, the waterproof case 6 prevents foreign matter from entering from the outside to the power conversion device 7. In one embodiment, the waterproof case 6 functions as a second member.

The power conversion device 7 is electrically connected to the battery cell 2 via a cable (not shown), and outputs the power from the battery cell 2 by converting a predetermined voltage or DC to AC.

The water channel cover 8 is formed so as to cover a portion of the supply pipe 9. The water channel cover 8 is formed so as to cover the opposing surface facing the upper surface of the power conversion device 7 so as to cover the supply pipe 9 exposed from the upper side of the power conversion device 7. The water channel cover 8 has one or more flow paths therein. In one embodiment, the water channel cover 8 functions as a first member.

The supply pipe 9 is disposed on the opposite surface facing an upper surface of the power conversion device 7, through the first hole 32, the second hole 61, and the power conversion device 7. With the supply pipe 9, refrigerant supplied from a pump (not shown), for example, water cools the junction box 10 and the battery cell 2 by circulating therein.

The junction box 10 is provided on top of the battery upper cover 4 controls the battery cell 2. The junction box 10 is disposed on an upper surface of the waterproof case 6, the upper surface is the facing surface facing the water path cover 8 through the waterproof case 6. The junction box 10 is connected to the battery cell 2 and the power conversion device 7 via a cable (not shown).

The equipment cover 11 is disposed on the upper surface of the battery upper cover 4 via the water stopping member 111, and is formed so as to cover the junction box 10 and the waterproof case 6.

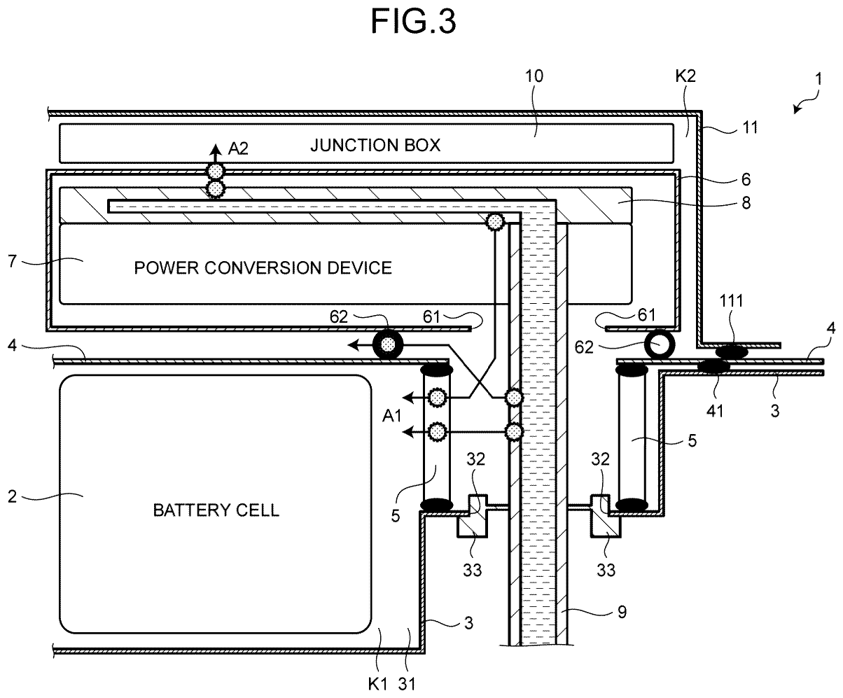

The sealing structure in the vehicle substructure 1 configured in this manner will be described. FIG. 3 is a diagram schematically illustrating the action by the seal structure in the vehicle substructure 1.

As illustrated in FIG. 3, if the water leaks in the vicinity of the power converter 7, the point Al between the supply pipe 9 and the ring-shaped water stop member 5 is double sealed by the supply pipe 9 and the ring-shaped water stop member 5. Thus, with the vehicle lower structure 1, even when water leaks from the supply pipe 9, it is possible to prevent water from entering the space K1 of the housing portion 31 in which the battery cell 2 is accommodated.

Further, in the position A2 between the waterway cover 8 and the waterproof case 6, the waterway cover 8 and the waterproof case 6, because it is sealed in duplicate, even if the water leaks from the supply pipe 9 or the waterway cover 8, the junction box 10 is accommodated it is possible to prevent the water from entering the space K2.

According to the embodiment described above, since the ring-shaped water cut-off member 5 blocks the opposite surface of the supply pipe 9 and the battery cell 2 is opposed to each other and is double sealed, when an impact is applied from the outside, when the supply pipe 9 is damaged, it is still possible to prevent the battery cell 2 from being watered by the cooling water leaking from the supply pipe 9.

Further, according to one embodiment, the waterproof case 6 is disposed on the upper surface of the battery upper cover 4 through the ring-shaped water stop member 62, houses the power conversion device 7 and the water passage cover 8 therein, and the water passage cover 8 and the junction box 10 including the supply pipe 9 for blocking the opposing surfaces facing, it is possible to prevent the junction box 10 is flooded by the cooling water leaked from the supply pipe 9.

Further effects and variations can be readily derived by one skilled in the art. The broader aspects of the disclosure are not limited to the specific details and representative embodiments expressed and described above. Accordingly, various changes may be made without departing from the spirit or scope of the overall inventive concept defined by the appended claims and their equivalents.

While some of the embodiments of the present application have been described in detail based on the drawings, these are illustrative, and it is possible to implement the present disclosure in other forms which are variously modified and improved based on the knowledge of those skilled in the art, starting from the aspects described in the column of the disclosure of the present disclosure.

According to the present disclosure, in the case where an impact is applied from the outside, when the water channel is damaged, an effect that it is possible to prevent the battery cell is submerged by the cooling water leaking from the water channel.

Although the disclosure has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A vehicle substructure comprising:
a battery cell;
a housing case having an opening and accommodating the battery cell;
a cover attached to the housing case in a state of covering the opening;
a junction box, provided on top of the cover, for controlling the battery cell;
a supply pipe for supplying a refrigerant for cooling the junction box and the battery cell;
a first member covering the supply pipe,
a second member for blocking an opposing surface where the supply pipe and the junction box face each other; and
a third member for blocking an opposing surface where the supply pipe and the battery cell face each other.

2. The vehicle substructure according to claim 1, further comprising a power conversion device for converting power from the battery cell, wherein
the housing case has a first hole in which the supply pipe is inserted,
the first member having least one refrigerant path through which the refrigerant flows, and being formed so as to cover an opposing surface which faces an upper surface of the power conversion device,
the second member, which has a second hole through which the supply pipe is inserted, is disposed on an upper surface of the cover, and accommodates the first member and the power conversion device, and
the supply pipe is connected to the first member through the first hole and the second hole, and supplies the refrigerant to the first member.

3. The vehicle substructure according to claim 2,
the junction box is disposed on an upper surface of the second member, and
the third member blocks an opposing surface where the supply pipe and the battery cell face each other between the cover and the housing case.
